(19) United States
(12) Patent Application Publication
(10) Pub. No.: US 2016/0027656 A1
(43) Pub. Date: Jan. 28, 2016

(54) DEFECT FREE SINGLE CRYSTAL THIN LAYER

(71) Applicant: KING ABDULLAH UNIVERSITY OF SCIENCE AND TECHNOLOGY, Thuwal (SA)

(72) Inventors: Rami Tarek EL AFANDY, Thuwal (SA); Boon S. OOI, Thuwal (SA)

(21) Appl. No.: 14/775,656

(22) PCT Filed: Mar. 14, 2013
(86) PCT No.: PCT/US2013/031441

§ 371 Date: Sep. 11, 2015

(51) Int. Cl. H01L 21/306; H01L 29/20

(52) U.S. Cl. CPC H01L 21/30617; H01L 29/2003

(57) ABSTRACT

A gallium nitride film can be a dislocation free single crystal, which can be prepared by irradiating a surface of a substrate and contacting the surface with an etching solution that can selectively etch at dislocations.

### TECHNICAL FIELD

The invention features a single crystal thin layer and methods of making

### BACKGROUND

Gallium nitride is a compound having a Wurtzite crystal structure and wide band gap of 3.4 eV. It has important applications in many fields, such as optoelectronics, high-power and high-frequency electronic devices, solid state devices, ultra high efficiency photovoltaic devices, and so on. The absence of free-standing seeding/substrate gallium nitride layer represents a significant challenge in the gallium nitride technology.

### SUMMARY

In general, a III-V semiconductor film, such as a gallium nitride film, can be dislocation free single crystalline. The III-V semiconductor film, such as a gallium nitride film, can have a thickness of between 10 nanometers to 1 micron, for example, between 10 nanometers and 200 nanometers or between 20 and 50 nanometers, and can be prepared by a combination of surface irradiation and chemical etching.

In one aspect, a method for preparing III-V semiconductor film can include irradiating a surface of a substrate including the III-V semiconductor, and contacting the surface of the substrate while irradiating with a solution containing an etching solution to form the film on the substrate.

In some embodiments, the III-V semiconductor can be selected from indium arsenide, indium phosphide, gallium arsenide, gallium phosphide, gallium antimonide, aluminum nitride, indium antimonide, aluminum arsenide, aluminum phosphide, aluminum antimonide, indium gallium arsenide, gallium arsenide phosphide, indium arsenide phosphide, indium gallium arsenide phosphide, indium aluminum gallium arsenide, indium gallium nitride, and aluminum gallium nitride. In some embodiments, the III-V semiconductor can be gallium nitride.

In some embodiments, the substrate can include a silicon doped, n-doped, un-doped (or un-intentionally doped), or p-doped gallium nitride on sapphire. In some embodiments, the substrate can include bulk gallium nitride. In some embodiments, the substrate can include gallium nitride on silicon carbide. In some embodiments, the substrate can include gallium nitride on silicon. Other kinds of substrate containing gallium nitride can also be used.

In some embodiments, the etching solution can include hydrogen fluoride and hydrogen peroxide. In some embodiments, the etching solution can include potassium hydroxide. In some embodiments, the surface of the substrate can include a plurality of dislocations. In some embodiments, the etching solution can etch selectively at the dislocations.

In some embodiments, the surface of the substrate can be irradiated by an irradiation source, wherein the irradiation source can have an energy greater than the bandgap of the III-V semiconductor or a wavelength below the bandgap of the semiconductor materials.

In some embodiments, the surface of the substrate can be irradiated by an ultraviolet light source, wherein the energy of the ultraviolet light source is greater than the bandgap of the III-V semiconductor. In some embodiments, the surface of the substrate can be irradiated by an X-ray. In some embodiments, the surface of the substrate can be irradiated by a gamma ray.

Both the length of the irradiation and the density of the irradiation source on the surface of the substrate affect the etching process. In some embodiments, the method can include controlling the intensity of the irradiation source. In some embodiments, a portion of the surface of the substrate can be coated with an electrode. In some embodiments, the material of the electrode can be selected from titanium, platinum, silver, and gold. In some embodiments, the method can include applying an electric field at the surface of the substrate. In some embodiments, the method can include drying the substrate.

In some embodiments, the thickness of the III-V semiconductor film can be between 10 nanometers to 1 micron, for example, between 10 nanometers and 200 nanometers or between 20 and 50 nanometers.

In some embodiments, the method can include transferring the III-V semiconductor film to a second substrate.

In another aspect, a film can include dislocation free single crystalline III-V semiconductor, wherein the dislocation free single crystalline III-V semiconductor can have a thickness of between 10 nanometers and 1 micron nanometers, for example, between 10 nanometers and 200 nanometers or between 20 and 50 nanometers.

In some embodiments, the film can include a plurality of pores. In some embodiments, the III-V semiconductor can be gallium nitride. In some embodiments, a plurality of gallium nitride wires can protrude through the dislocation free single crystalline gallium nitride. In some embodiments, the film can include a porous gallium nitride layer underneath the dislocation free single crystalline gallium nitride.

In another aspect, a structure can include dislocation free single crystalline III-V semiconductor on a substrate, wherein the substrate can be a polymer substrate, copper substrate, silicon substrate, glass substrate, silicon carbide substrate, sapphire substrate, quartz substrate, porcelain substrate, indium phosphide substrate, gallium nitride substrate, gallium arsenide substrate, beryllium oxide substrate, aluminum nitride substrate, alumina substrate, plastic substrate, or ceramic substrate.

In another aspect, a device for growing III-V semiconductor can include a film, wherein the film includes dislocation free single crystalline III-V semiconductor, and wherein the film can have a thickness of 10 nanometers to 1 micron, for example, between 10 nanometers and 200 nanometers or between 20 and 50 nanometers. After transferring the film, gallium nitride, indium gallium nitride, aluminum nitride, zinc oxide, Indium tin oxide or other materials can be overgrown on the film through which transistors, modulators, light-emitting diodes, laser diodes can be made.

In some embodiments, the III-V semiconductor is gallium nitride.

Other aspects, embodiments, and features will be apparent from the following description, the drawings, and the claims.

### BRIEF DESCRIPTION OF THE DRAWINGS

FIG. 1 is a schematic drawing showing the formation of dislocation free gallium nitride layer on a bulk gallium nitride substrate.

FIG. 2 shows an exemplary UV-assisted electroless etching setup for the fabrication of the Gallium nitride film.

FIG. 3a is a top view scanning electron microscope (SEM) micrograph showing the hexagonal etch pits forming on the surface; FIG. 3b is a cross sectional SEM micrograph of a nascent pore domain, a nanowire is observed in the middle of the pore domain, and the boundary of the domain is marked in black; FIG. 3c is an image showing a relatively older pore domain encompassing porous gallium nitride formed of a primary and secondary pores, the vertical and horizontal arrows represent the fast anisotropic and the slow isotropic etch processes, respectively; FIG. 3d is an image showing that a nano-layer is supported by few columns after the domains have coalesced; FIG. 3e is an image showing a nano-layer lying on a porous gallium nitride layer on top of the bulk gallium nitride; and FIG. 3f is an image showing that the pore domains are exposed after the mechanical removal of the gallium nitride nano-layer where the centers of the domains are marked by black spots and the boundary of one domain is marked by a curve.

FIG. 4 is a series of cross sectional images of gallium nitride nano-layer lying on porous gallium nitride.

FIG. 5 shows top view of the nano-layer (top left) onto a porous gallium nitride (bottom right).

FIG. 6a is an SEM image showing the tips of the NWs below the surface etch pits; FIG. 6b is a schematic drawing showing the gallium nitride nano-layer on top of porous gallium nitride with a nanowire (NW) formed from a TD lying exactly below the hexagonal etch pit; FIG. 6c is a cross sectional image; and FIG. 6d is a top view SEM image of nanowires protruding through the etch pits in the gallium nitride layer.

FIG. 7a is a cross sectional SEM image of a bombarded sample with Ar+ ions after t min of UV assisted electroless etching, where the dashed lines present the etching fronts which propagate vertical at first then radial; and FIG. 7b is an SEM image showing the NWs embedded in the porous etch domain

FIG. 8a is a transmission electron microscopy (TEM) image of a gallium nitride layer after transfer onto a carbon coated cupper transmission electron microscopy (TEM) grid; FIG. 8b is a High-resolution transmission electron microscopy (HRTEM) of the gallium nitride layer pictured along the [0001] zone axis, which shows a perfect hexagonal crystalline structure of the nano-layer, and the inset of FIG. 9b is the electron diffraction (ED) pattern recorded along the [0001] zone axis with the marked (10 1̅0), (0 1̅10) and ( 1̅100) diffraction spots; and FIG. 8c is the measured EDS spectrum from the gallium nitride nano-layer.

FIG. 9a is an SEM image of the surface etch pit in direct contact with the nanowire tip; FIG. 9b is a TEM image of the surface etch pit present in the nano-layer; and FIG. 9c is a HRTEM image of the center of the pit showing a perfect single crystalline structure.

FIG. 10 is a measured micro-photoluminescence (μPL) emission signal from the gallium nitride nano-layer showing a strong peak at 3.4 eV; inset (a) shows the transferred gallium nitride layer onto a sapphire substrate as observed through an optical microscope; and inset (b) shows a schematic of the gallium nitride nano-layer onto sapphire while being probed by a UV laser focused by an objective lens.

### DETAILED DESCRIPTION

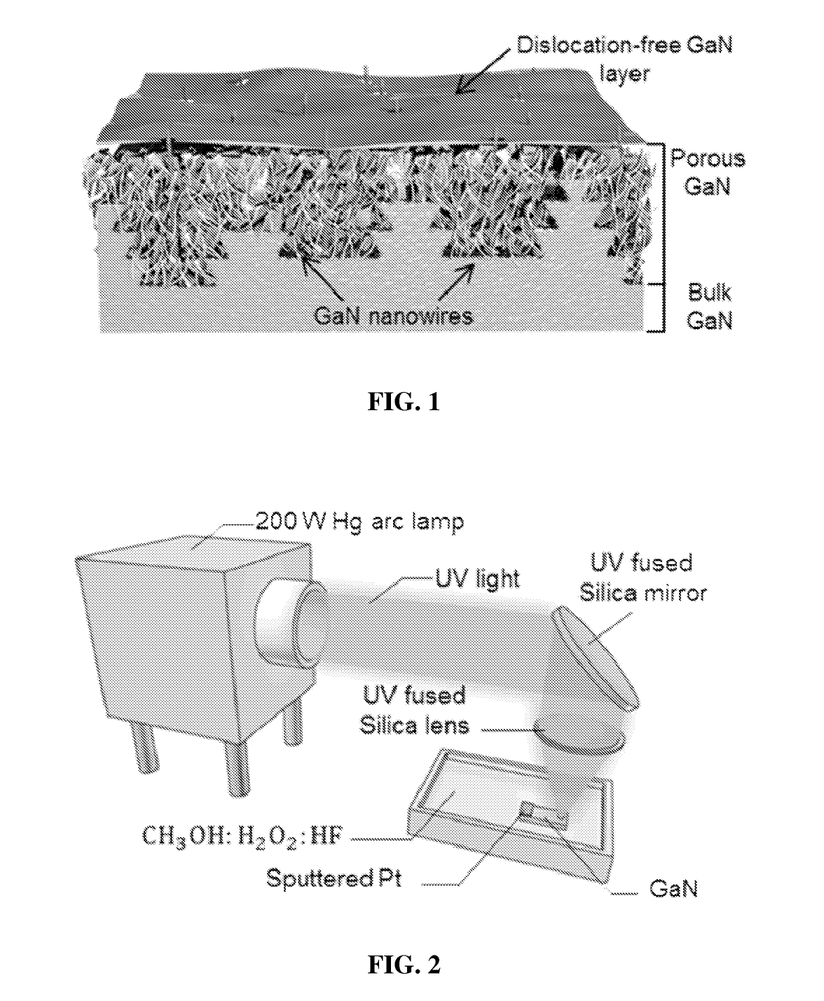

A dislocation free single crystalline III-V semiconductor, such as gallium nitride, layer (or nano-layer, or film, or nano-membrane) with a thickness of 10 nanometers to 1 micron, for example, between 10 nanometers and 200 nanometers or between 20 and 50 nanometers can be produced by irradiation, such as ultraviolet (UV), assisted electroless chemical etching, a cost effective and energy efficient technique. The dislocation free single crystalline III-V semiconductor, such as gallium nitride, layer can be formed, for example, by exfoliating from an original crystal having a 10⁸cm⁻² (threading dislocation density) TDD after all the threading dislocations (TDs) are selectively etched away. The III-V semiconductor, such as gallium nitride, thin layer can subsequently be transferred to a foreign substrate for subsequent epitaxial growth of high quality gallium nitride and its related materials. FIG. 1 is a schemtic drawing showing the formation of dislocation free gallium nitride layer on a bulk gallium nitride substrate; the layer can be supported by a plurality of gallium nitride nanowires with some protruding through the surface.

Scanning and transmission electron microscopy (SEM and TEM) observations can help explain the physical processes behind the formation of the gallium nitride nano-layer. Further, electron microscopy and optical spectroscopy techniques reveal the single crystalline nature of the gallium nitride nano-layer. The dislocation free gallium nitride nano-layer can be transferred to a variety of hard or flexible substrates and function as a seed layer for subsequent epitaxial over-growth of dislocation free, high quality gallium nitride. The substrate can be polymer substrate, copper substrate, silicon substrate, glass substrate, silicon carbide substrate, sapphire substrate, quartz substrate, porcelain substrate, indium phosphide substrate, gallium nitride substrate, gallium arsenide substrate, beryllium oxide substrate, aluminum nitride substrate, alumina substrate, plastic substrate, or ceramic substrate.

The membrane can be transferred using already developed printing/stamping transfer techniques. Yuan, H. C., et al. Appl. Phys. Lett. 2009, 94, 013102; Sun, L., et al. Small 2010, 6, 2553-2557, each of which is incorporated by reference in its entirety. The membrane can be easily transferred to Silicon electronics and thus enabling the fast integration between Silicon and high quality gallium nitride (or similar materials).

This technology can pave the way for high efficiency low cost optoelectronic and high power electronic device applications, and facilitate the fast integration between high quality gallium nitride and other material systems such as silicon or plastics.

A dislocation free single crystalline III-V semiconductor layer (or nano-layer, or film) can have a thickness of 10 nanometers to 1 micron, for example, between 10 nanometers and 200 nanometers or between 20 and 50 nanometers. The layer can be produced by irradition assisted electroless chemical etching. The III-V semiconductor can include indium arsenide, indium phosphide, gallium arsenide, gallium phosphide, gallium antimonide, indium antimonide, aluminum arsenide, aluminum phosphide, aluminum antimonide, indium gallium arsenide, gallium arsenide phosphide, indium arsenide phosphide, indium gallium nitride, aluminum gallium nitride, or gallium nitride.

Gallium nitride is an example of III-V semiconductor. The compound has a Wurtzite crystal structure and wide band gap of 3.4 eV. It has important applications in many fields, such as optoelectronic, high-power and high-frequency electronic devices, solid state devices ultra high efficiency photovoltaic devices, and so on.

Gallium nitride based light emitting diodes (LEDs) and laser diodes (LDs) have ushered the way for several staggering technologies including solid-state lighting, high-density optical data storage, high power electronics and laser based projectors and TVs. See, for example, Ponce, F., et al., Nature 1997, 386, 351-359, which is incorporated by reference in its entirety. Further scientific advancements and technological breakthroughs are however hindered by the reliance on the existing relatively low cost heterogeneous substrates. Having large thermal and lattice mismatches, the resulting hetero-epitaxy in commercial gallium nitride template substrates (gallium nitride -on-sapphire or gallium nitride-on-SiC) has high TDD (see, Lester et al. Applied Physics Letters 1995, 66, 1249) of 10⁷-10¹⁰cm⁻² causing a decrease in the quantum efficiency and a reduction in the device lifetime. See, for example, Kim, H. -M., et al., Nano letters 2004, 4, 1059-1062; Schubert, M. F., et al., Applied Physics Letters 2007, 91, 231114; Lester, S. D., et al., Applied Physics Letters 1995, 66, 1249, each of which is incorporated by reference in its entirety.

Researchers have been relentlessly working on epitaxial transfer and/or thick layer (30-300 μm) regrowth using metal-organic chemical vapor deposition (MOCVD), or hydride vapor phase epitaxy (HYPE), essentially to achieve ˜10⁶ cm⁻² pseudo-gallium nitride single crystal substrate. See, for example, Paskova, T., et al., Selected Topics in Quantum Electronics, IEEE Journal of 2009, 15, 1041-1052; Paskova, T., et al., Proceedings of the IEEE 2010, 98, 1324-1338, each of which is incorporated by reference in its entirety. Several techniques are implemented to decrease TDD within the material including, epitaxial lateral overgrowth (ELOG), dislocation filtering, the growth of Aluminum nitride (AlN) or gallium nitride low temperature buffer layers, or overgrowth on porous or gallium nitride nanocolumns. See, for example, Nam, O. H., et al., Applied physics letters 1997, 71, 2638-2640; Colby, R., et al., Nano letters 2010, 10, 1568-1573; Yoshida, S., et al., Applied Physics Letters 1983, 42, 427-429; Bai, J., et al., Journal of Applied Physics 2006, 99, 023513; Kang, J. H., et al., Journal of Crystal Growth 2012; Tang, T. Y., et al., Journal of Applied Physics 2009, 105, 023501-023501-8, each of which is incorporated by reference in its entirety. Though the TDD is reduced to 10⁵ cm⁻³ for the ELOG, the absence of free-standing seeding/substrate layer represents the most significant challenge in the gallium nitride photonics technology. See, for example, Marchand, H., et al., Applied Physics Letters 1998, 73, 747-749, which is incorporated by reference in its entirety. While ammonothermal growth can grow gallium nitride with TDD as low as 10⁴ cm⁻², the process is relatively costly, energy hungry and suffers from very slow growth rate which makes its commercialization challenging. See, for example, Hashimoto, T., et al., Japanese Journal of Applied Physics 2005, 44, L797-L799; Dwiliński, R., et al., Journal of Crystal Growth 2008, 310, 3911-3916, each of which is incorporated by reference in its entirety.

Other methods included growing gallium nitride nanowires or nano-pyramids onto different substrates since these nanostructures are characterized by a lower threading dislocations (TDs). See, for example, Schuster, F., et al., Nano Letters 2012, 12, 2199-2204; Guo, W., et al., Nano letters 2010, 10, 3355-3359; Choi, J. H., et al., Nature Photonics 2011, 5, 763-769, each of which is incorporated by reference in its entirety. There exists, however, a technology gap in which epitaxial films of gallium nitride with low TDD can be grown on different substrates of different lattice constants and thermal coefficients in a high throughput, cost effective and energy efficient manner.

In addition, for a gallium nitride seed layer to be effective for subsequent epitaxial overgrowth, the seed layer is preferably to have a single crystalline structure. Otherwise, structural dislocation will nucleate around crystal imperfections causing the overgrown of defective gallium nitride.

Etching of Gallium Nitride Chemical etching of n-gallium nitride can depend on the presence of a surface charge region (SCR) at the gallium nitride/electrolyte interface which arises due to gallium nitride surface Fermi-level equilibration with the electrochemical potential of the electrolyte. See, for example, Rajeshwar, K., Encyclopedia of Electrochemistry 2007, which is incorporated by reference in its entirety. This SCR is characterized by the presence of surface electrical fields ( [symbol] -fields) which causes an upward bending in the conduction and valence bands. Photo-assisted chemical etching of n-gallium nitride occurs when incident photons, with energy more than the gallium nitride bandgap, excite electron-hole (e⁻, h⁺) pairs. If the pairs are excited away from the SCR they will simply recombine rendering them useless for surface reactions. However, if they are generated at most at a distance equal to the hole diffusion length away from the SCR, holes may diffuse to the SCR where they will drift towards the interface under the effect of the [symbol] -fields. Since holes are simply broken bonds, once the photo-generated holes reach the gallium nitride/electrolyte interface, they increase surface atoms energy causing the oxidation of the gallium nitride surface to gallium oxide (Ga₂O₃) according to the following oxidation reaction.

2GaN(s)+6h⁺+3H₂O(l)→Ga₂O₃(s)+6H⁺(aq)+N₂(g)

See, for example, Minsky, M., et al., Applied Physics Letters 1996, 68, 1531-1533; Youtsey, C., et al., Journal of Electronic Materials 1998, 27, 282-287; Vajpeyi, A., et al., Physica E: Low-Dimensional Systems and Nanostructures 2005, 28, 141-149, each of which is incorporated by reference in its entirety.

After oxidation, Ga₂O₃ can be etched away by HF. Methanol can be added to reduce the solution surface tension allowing the produced N₂ gas not stick to the gallium nitride surface which would have prevented further etching from proceeding. As for the photo-generated electrons, they can be collected by an electrode (for example, a platinum electrode) where they contribute in the reduction of hydrogen peroxide present at the platinum/electrolyte interface. See, for example, Vajpeyi, A., et al., Physica E: Low-Dimensional Systems and Nanostructures 2005, 28, 141-149, which is incorporated by reference in its entirety.

3H₂O₂+6e⁻+6H⁺6H₂O

### Selective Etching at the Dislocations of a Gallium Nitride Substrate

When the surface of a gallium nitride substrate includes a plurality of dislocations, the etching solution can etch selectively at the dislocations. The intensity of the surface internal [symbol] -fields for curved semiconductor/electrolyte interfaces can be calculated. See, for example, Zhang, X., Journal of the Electrochemical Society 1991, 138, 3750-3756, which is incorporated by reference in its entirety. In the presence of surface pits, with a semi-spherical tip, the surface [symbol] -fields are highly enhanced at the tip and thus, once photo-generated holes reach the depletion region, they drift faster towards the tip of the pit causing a faster etching at the tip. Previously published researches demonstrate, through atomic force microscopy (AFM) and TEM measurements, that TDs terminating at the gallium nitride surface cause the formation of surface depressions. See, for example, Youtsey, C., et al., Applied Physics Letters 1999, 74, 3537-3539; Visconti, P., et al., Applied Physics Letters 2000, 77, 3532-3534; Sasaki, H., et al., Japanese Journal of Applied Physics 2006, 45, 2531, each of which is incorporated by reference in its entirety. These surface depressions, with enhanced local [symbol] -fields, should have a higher density of photo-generated holes and thus, the hexagonal surface pits are expected to initiate at these depressions. This suggests that the TDs, although originally present in the bulk, can be etched away in the surface layer due to the induced surface depressions.

In order to shed light on the processes responsible for the gallium nitride nano-layer formation, the reasons behind the nucleation of the surface hexagonal etch pits can be analyzed. Surface etching through pit formation indicates a non-uniform dissolution rate among the microscopic sites on the gallium nitride surface available for etching. Such a non-uniformity arises from one of the several possible limiting factors including: holes photo-generation, holes transport to the interface and reactants and products respective inward and outward fluxes to the interface. In some embodiments, using a magnetic stirrer to enhance the chemical fluxes does not change the observation, crossing out the possibility that the non-uniformity arises from unequal surface concentrations of the reactants or products. It can be assumed that, on the microscopic scale, the UV intensity across the gallium nitride surface is uniform, leading to an even holes generation rate on the microscopic scale.

This leaves the holes transport to the interface as the most legitimate rate-limiting factor. Furthermore, gallium nitride is characterized by a low hole mobility and thus, and it can be assumed that the drift of photo-generated holes to the interface, under the effect of the surface [symbol] -fields in the depletion region, is the decisive factor for etching. See, for example, Mnatsakanov, T. T., et al., Solid-State Electronics 2003, 47, 111-115, which is incorporated by reference in its entirety.

Formation of Gallium Nitride Film with Low Irradiation Intensity

While n-type gallium nitride UV-assisted etching in CH₃OH:H₂O₂:HF has been reported, no prior published work reports on the formation of a thin single crystalline gallium nitride layer. See, for example, Williamson, T. L., et al., Journal of Applied Physics 2003, 94, 7526-7534; Li, X., et al., Applied Physics Letters 2002, 80, 980-982; Chuah, L., et al., Materials Science-Poland 2008, 26, (3), each of which is incorporated by reference in its entirety.

To form a single crystalline gallium nitride layer, a focusing lens can be used to create an optical power density and hence, a charge carrier concentration gradient across the sample surface. The sample surface can be in contact with an etching solution.

A dislocation free single crystalline gallium nitride film can be prepared using UV-assisted etching. A method for preparing gallium nitride film can include irradiating a surface of a gallium nitride substrate, and contacting the surface of the gallium nitride substrate while irradiating with a solution containing an etching solution to form the film on the substrate. Irradiation can come from various sources, such as UV light. The gallium nitride substrate can be a gallium nitride wafer. The etching solution can include hydrofluoric acid, hydrogen peroxide, potassium hydroxide, or methanol, or a combination thereof

A gallium nitride film can be formed through a combination of a vertical etching and a lateral etching below the surface of a gallium nitride substrate. In some embodiments, an HF based etching solution can first attack the cleaned surface of a gallium nitride substrate causing hexagonal etch pits to form. Etching can then proceed rapidly along the [000 1̅] crystallographic direction causing the surface pores to get deeper. However, at a certain depth from the surface, along with the rapid vertical crystallographic etching mechanism, a second slower anisotropic lateral etching mechanism can appear. The depth from the surface can be from 10 nanometers to 1 micron, for example, between 10 nanometers and 200 nanometers or between 20 and 50 nanometers. This second etching mechanism can cause the pores to widen, however at a much slower rate than their vertical propagation. The presence of these two etching mechanisms can cause the formation of undersurface cavity like structures. As undersurface gallium nitride gets etched away, a floating thin layer can be formed on top of a porous gallium nitride layer. The thin layer can have a thickness of 10 nanometers to 1 micron, for example, between 10 nanometers and 200 nanometers or between 20 and 50 nanometers.

It is preferred that the irradiation intensity on the surface of the substrate is low. A high irradiation intensity can etch away the dislocation free single crystalline gallium nitride film. Both the length of the irradiation and the density of the irradiation source on the surface of the substrate affect the etching process. The irradiation source can be any source having a higher energy than the bandgap of the semiconductor film to be prepared, or any source having wavelengths below the bandgap of the semiconductor materials. Examples of the irradiation source include UV light, x-ray, and gamma rays. If a certain energy density causes the formation of the membrane without applying a bias, a higher intensity can still be used if a bias is applied. So the maximum intensity can be a function of the applied bias. And the energy density (or energy intensity) of the irradiation source at the surface of the substrate can be adjusted or controlled to optimize the etching result.

In some embodiments, the light can focus on a portion of the surface of the gallium nitride substrate. While the portion of the surface under irradiation may be etched away, the portion of the gallium nitride substrate not under direct irradiation can produce dislocation free single crystalline gallium nitride layer. The irradiation intensity on the surface of the gallium nitride substrate can be changed or controlled by using optics, such as filters, optical attenuator, optical diffuser, beam expander, or polarizer, a combination thereof.

A threading dislocation free single crystalline gallium nitride nano-layer can be prepared using a simple, inexpensive and energy efficient UV-assisted electroless etching technique. Scanning electron microscopy can be used to study the detailed formation process of the gallium nitride nano-layer. TEM, EDS and μPL measurements can confirm the single crystalline nature of the gallium nitride nano-layer. Through this method, a dislocation free single crystalline gallium nitride nano-layer can be exfoliated from an original crystal having high TDD, such as 10⁸ cm⁻² TDD, after all the TDs are selectively etched away. This layer can be transferred to other hard or flexible substrates and serves as a seed layer for subsequent epitaxial growth of dislocation free, high quality gallium nitride. See, for example, Rogers, J., et al., Nature 2011, 477, 45-53, which is incorporated by reference in its entirety. This technology will facilitate the fast integration between high quality gallium nitride and other material systems such as silicon or plastics enabling the production of cost efficient, high quality optoelectronic and electronic devices.

Gallium nitride thin film can be prepared from a substrate containing a silicon doped c-plane oriented gallium nitride on sapphire, n-doped, un-doped or p-doped gallium nitride can also be used; gallium nitride thin film can be prepared from a substrate containing bulk gallium nitride; gallium nitride thin film can be prepared from a silicon carbide substrate containing gallium nitride; gallium nitride can be prepared from a silicon substrate containing gallium nitride; and gallium nitride can be prepared from other substrates containing gallium nitride.

### EXAMPLES

### Formation and Characterization of a Gallium Nitride Film

The gallium nitride wafers used in this study consist of 30 μm of silicon doped (˜10¹⁰ cm³) c-plane oriented gallium nitride grown using metal-organic chemical vapor deposition (MOCVD) technique on a sapphire substrate. The wafer has an initial TDD of 10⁸ cm⁻². The gallium nitride wafer was cleaved into 7×7 mm² pieces which are later degreased in acetone and isopropanol alcohol (IPA), respectively for 5 mins and finally cleaned in hot HNO3 (65° C.) for 15 mins for surface oxide removal. Some other samples are further cleaned into HCL for 10 mins or in HF for 2 hours to be certain of a complete surface oxide removal. See, for example, Ohira, S., et al., Physica Status Solidi (c) 2008, 5, 3116-3118, which is incorporated by reference in its entirety. The effect of the different cleaning procedures on the final results was not observed. A thin layer of platinum metal (150 nm) is sputtered on the side of each of the samples which are later immersed in an electrolyte composed of 1:2:2 CH₃OH:H₂O₂:HF with the c-plane in contact with the solution. In addition to platinum, titanium, gold or silver can also be used as electrode. In some embodiments, an electric field can be applied at the surface of the substrate during etching. The electrodes can have different configurations, such as standard electrode configuration. A fused silica lens is used to focus ultraviolet (UV) light emanating from a 200 W mercury (Hg) arc lamp onto the sample (FIG. 2). Once the desired etching period is reached, the sample is cleaned by dipping and rinsing in IPA and then dried using a critical point dryer (CPD).

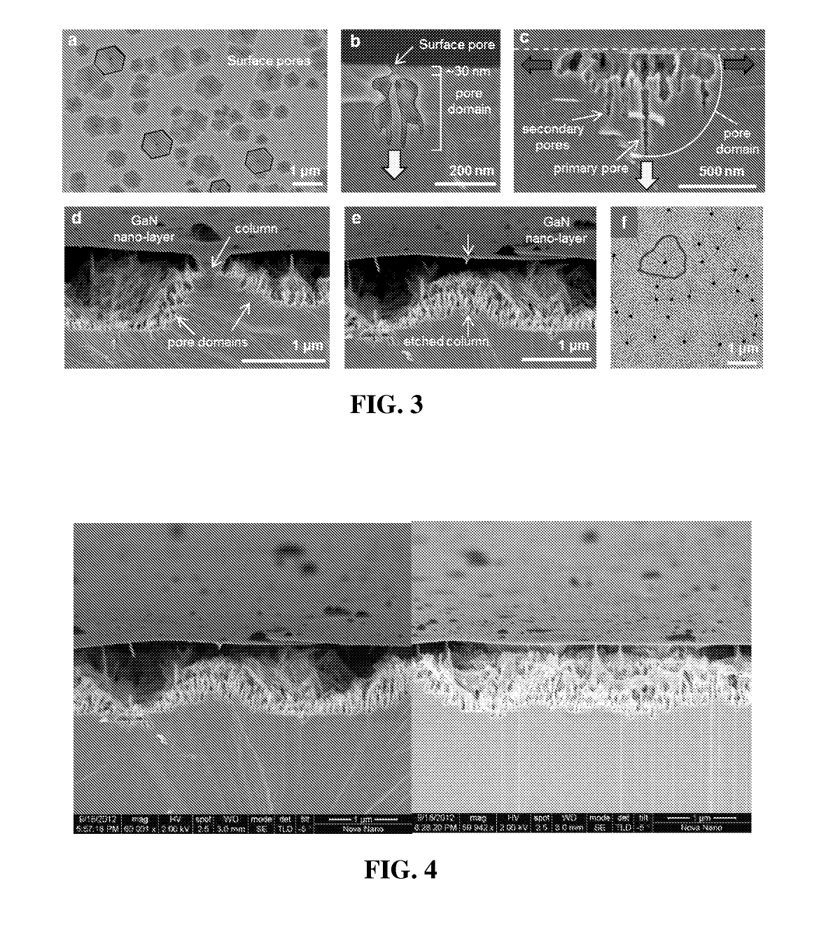

FIG. 3 is a series of scanning electron microscope SEM micrographs showing different stages along the layer formation. The HF based electrolyte solution first attacks the cleaned surface of the gallium nitride causing hexagonal etch pits to form (FIG. 3a). These surface pores nucleate at terminations of TDs. Once pores nucleate at the surface, etching proceeds rapidly along the [000 1̅] crystallographic direction causing the surface pores to get deeper (represented by the arrow pointing down in FIG. 3b). However, at certain depth from the surface, along with the rapid vertical crystallographic etching mechanism, appears a second slower anisotropic lateral etching mechanism. The depth from the surface can be from 10 nanometers to 1 micron, for example, between 10 nanometers and 200 nanometers or between 20 and 50 nanometers. This second etching mechanism causes the pores to widen, however at a much slower rate than their vertical propagation. See, for example, Feenstra, R. M., et al., Porous Silicon Carbide and Gallium Nitride: Epitaxy, Catalysis, and Biotechnology Applications. Wiley: 2008, which is incorporated by reference in its entirety. As the anisotropic etching proceeds laterally (represented by arrows pointing left and right in FIG. 3c), secondary vertical pores nucleate and propagate crystallographically along the [000 1̅] direction (FIG. 3c). The presence of these two etching mechanisms causes the formation of undersurface cavity like structures, or pore domains, which encompass a group of spatially confined vertical pores with a tiny opening at the top (FIG. 3c). See, for example, Erne, B., et al., Journal of the Electrochemical Society 1996, 143, 305-314; O'Dwyer, C., et al., Journal of The Electrochemical Society 2007, 154, H78-H85, which is incorporated by reference in its entirety. At this stage, reactants and products need to diffuse in and out, respectively, from the tiny surface opening for etching to proceed. Since the pore domains are only embedded 10 nanometers to 1 micron deep from the surface, for example, between 10 nanometers and 200 nanometers or between 20 and 50 nanometers, a considerable amount of UV photons can still reach them generating e-h pairs on the domain walls causing the UV assisted etching of gallium nitride to proceed.

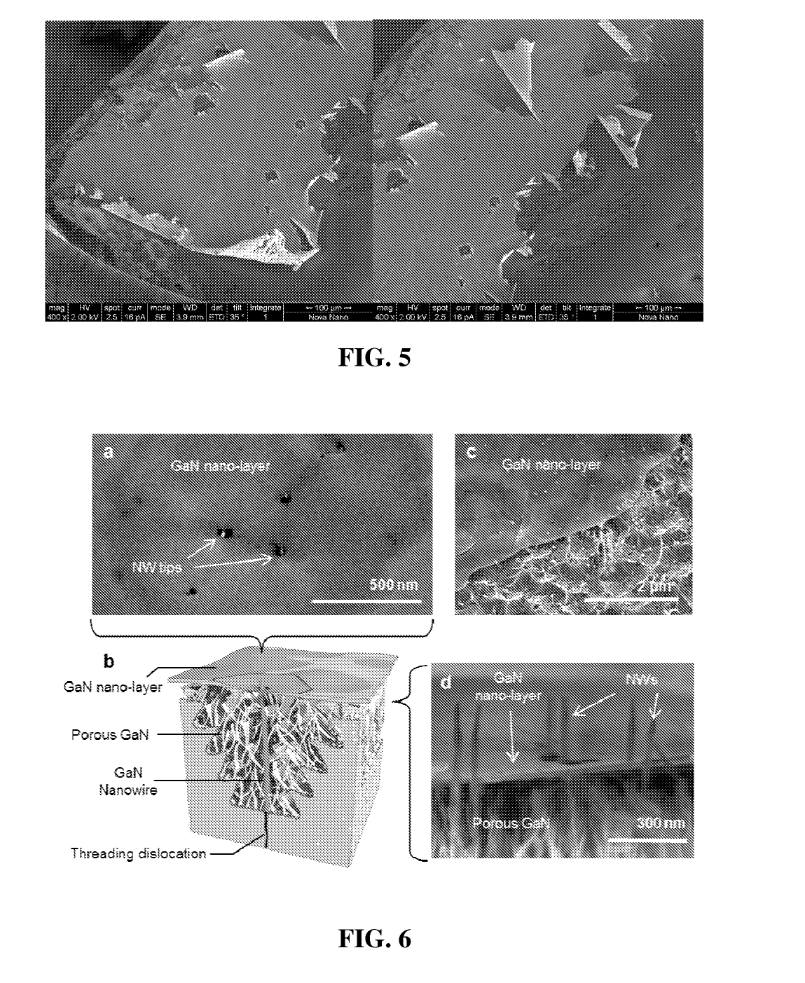

As undersurface gallium nitride gets etched away, the pore domains become wider till they coalesce forming larger ones. Later, the surface layer is only supported by few columns which eventually get etched away forming a floating 10 nanometers to 1 micron thin layer, for example, between 10 nanometers and 200 nanometers or between 20 and 50 nanometers, on top of a porous gallium nitride layer (FIG. 3d and FIG. 3e). The pore domains are imaged in FIG. 3f after the mechanical removal of the thin surface layer where the centers of the pore domains are marked by black spots and the boundary of one pore domain is marked by the red curve. As the sample dries, due to the water surface tension, the thin layer collapses downward and sticks to the porous gallium nitride. In order to overcome this sticking, which makes it nearly impossible for a subsequent mechanical exfoliation, the gallium nitride samples can be dried using CPD in liquid carbon dioxide. Some samples, after they are cleaned, are dipped in HF (50%) for 2 hours without the presence of UV or H₂O₂, which should be enough to dissolve any remaining formed oxides. See, for example, Ohira, S., et al., Physica Status Solidi (c) 2008, 5, 3116-3118, which is incorporated by reference in its entirety. FIG. 4 shows cross-sectional images of the gallium nitride nanolayer lying on porous gallium nitride. FIG. 5 shows top view of the nano-layer (top left) onto the porous gallium nitride (bottom right).

According to the previous oxidation reaction, six holes are required to oxidize two Ga atoms and thus, at any surface where the hole concentration is less than the threshold (hₜₕ⁺=3 h⁺/Ga atom) etching will not proceed. See, for example, Weyher, J., et al., The European Physical Journal Applied Physics 2004, 27, 37-41, which is incorporated by reference in its entirety. During the UV-assisted electroless etching of gallium nitride, the formation of nanowires, or whiskers, is attributed to the presence of TDs which offer fast recombination channels for the e-h pairs and thus decrease the surrounding hole concentration below hₜₕ⁺ preventing etching of the surrounding volume. See, for example, Youtsey, C., et al., Applied Physics Letters 1998, 73, 797-799; Weyher, J., et al., Journal of Applied Physics 2001, 90, 6105-6109, each of which is incorporated by reference in its entirety. The SEM images show the tips of the NWs directly below the surface etch pits (FIG. 6a) and thus in the middle of each of the undersurface cavities lies one gallium nitride NW (see FIG. 3b). This implies that the surface etch pits nucleate at the surface terminations of the TDs causing the formation of a TD free gallium nitride nano-layer. When the layer collapses downward under the effect of the water surface tension, the NWs can protrude through the holes which are present just on top of them (FIG. 6c and FIG. 6d).

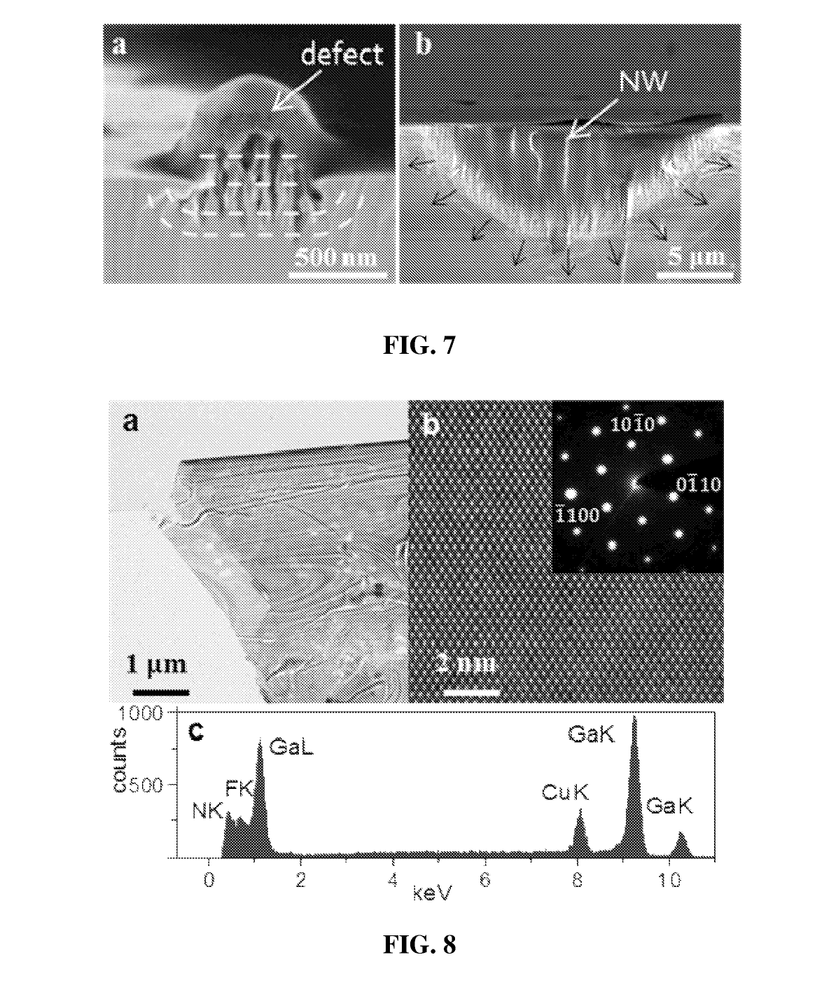

To further prove the concept, that the exfoliated nano-layer is TD free, surface defects were created through Argon ion (Ar) bombardment using inductive coupled plasma and then later etched the sample in the HF solution under UV illumination. FIG. 7a presents SEM image of a surface defect after 1 min of etching. It can be seen that etching initiates at the defect site and later propagates downward. Once the etching front reaches the bulk gallium nitride, it becomes radial causing the formation of the gallium nitride nano-layer. However, as observed in FIG. 7b, the domains are not formed around NWs, formed from TDs, but rather around the surface induced defects. This indicates that in that layer, all the TDs still exist which will act as dislocation nucleation sites if used for regrowth. However, the domains form around the NWs indicating that the TDs within the surface nano-layer got etched away during the exfoliation process.

### Demonstration of Defect Free Single Crystal Gallium Nitride Film

Since any remaining crystal dislocations act as dislocation nucleation sites during overgrowth, the dislocated crystal can be completely etched away during exfoliation.

In order to get TEM micrographs of the nano-layer, a piece of the thin film is transferred to a carbon coated copper grid (FIG. 8a). The high resolution TEM (HRTEM) of the layer aligned to the c-plane is presented in FIG. 8b, with the inset showing the associated electron diffraction (ED) pattern. A high degree of crystallinity of the hexagonal lattice is observed. Measuring the interplanar distances from the (10 1̅0), (0 1̅10) and ( 1̅100) diffraction spots yields a value of 2.738 Å which is equal to the tabulated data for the unstrained gallium nitride. These results indicate that the exfoliated layer is a single crystal gallium nitride thin nano-layer. The exfoliation of a dislocation free single crystalline gallium nitride thin film using a non-intrusive method has not been reported. Such a nano-layer, where TDs are etched away, does not contain any dislocation nucleation sites if used for subsequent growth. The collected energy dispersive X-ray spectroscopy (EDS) spectrum from the gallium nitride layer in FIG. 8c shows no peaks other than that associated with N, fluorine (F) and Ga. The F peak is believed to originate from residual F halogens that tie up with the Ga dangling bonds at the surface which is usually the case after nitrides exposure to HF. See, for example, King, S., et al., Journal of Applied Physics 1998, 84, 5248-5260, which is incorporated by reference in its entirety.

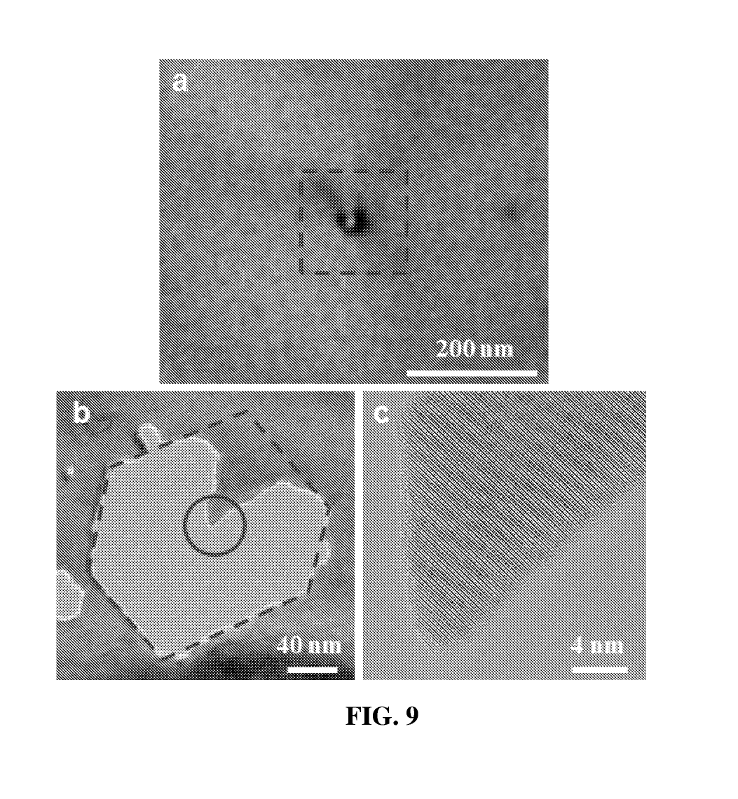

The SEM image in FIG. 9a shows that the tip of the gallium nitride NW is in direct contact with the etch pit present in the nano-layer. Since NWs are formed from etch resistant TDs, it is important that after exfoliation, there are no remnants of TDs in the nano-layer. FIG. 9b shows a TEM image of the etch pit present on the nano-layer which is highlighted with a dashed square in FIG. 9a. While the top of a typical etch pit is hexagonal (FIG. 3a), the bottom looks more like a heart shape where the supposedly formed hexagon pit (dashed lines in FIG. 9b) got distorted by the fact that the TD did not allow any etching of its surrounding. A HRTEM image of the center of the hexagon (solid circle in FIG. 9b), where the NW tip was in direct contact with the nano-layer's crystal is shown in FIG. 9c. It is single crystalline indicating that the entire dislocated crystal is completely etched away.

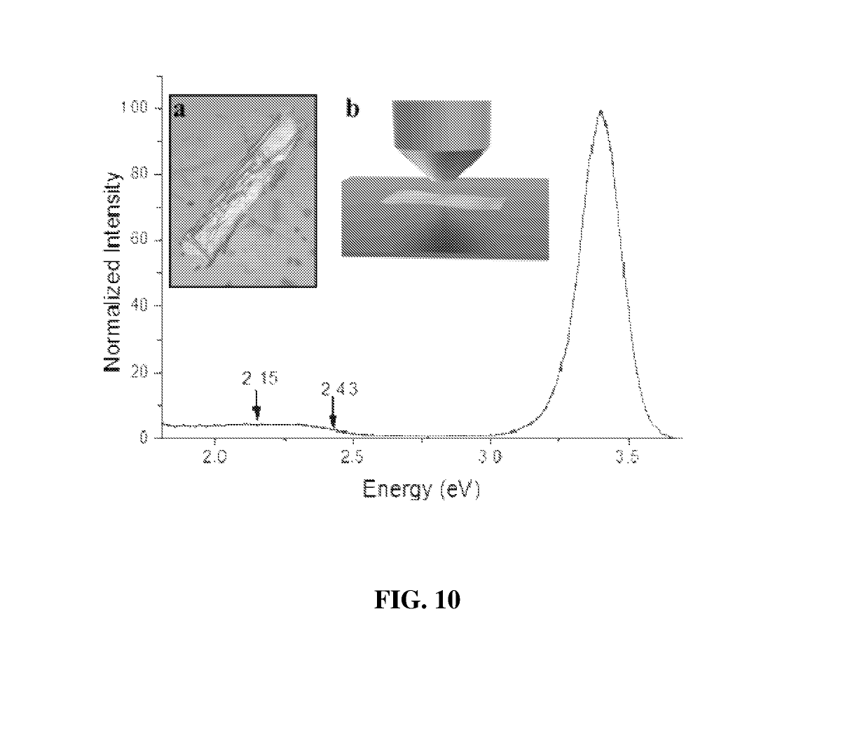

TEM measurements show that the exfoliated nano-layer is single-crystalline, with no TDs observed in all specimens under study. The optical properties of the nano-layer were further characterized using micro-photoluminescence (μPL). In order to remove any interference from the much stronger μPL signal of the underlying porous and bulk gallium nitride, the nano-layer can be transferred onto a sapphire substrate (E_{g}=9.9 eV) as shown in inset a of FIG. 10. A 325 nm laser (E_{exc}=3.8 eV) is focused to a spot size of 28 μm² (see inset b of FIG. 10) and the recorded RL data is shown in FIG. 10. The gallium nitride nano-layer exhibits a μPL at 3.4 eV which is the characteristic band to band transition in the gallium nitride. The emission intensity at 2.15 eV (yellow luminescence) and at 2.43 eV (Green luminescence), which are attributed to different types of structural defects in the gallium nitride are incomparable with the 3.4 eV emission indicating that the layer's defects density is relatively low. See, for example, Reshchikov, M., et al., Applied Physics Letters 2001, 78, 3041-3043, which is incorporated by reference in its entirety. This is in agreement with the observation based on SEM and TEM measurements. There were previous successful efforts of forming a gallium nitride ultra-thin membrane using bombardment with Argon ions followed by etching in potassium hydroxide (KOH). See, for example, Tiginyanu, I., et al., Materials Letters 2011, 65, 360-362; Tiginyanu, I., et al., Physica Status Solidi (RRL)-Rapid Research Letters 2012, each of which is incorporated by reference in its entirety. However, the formed membranes reported previously exhibit a peak cathodoluminescence emission at 2.2 eV indicating that they are mainly formed from defective gallium nitride generated by Argon ions bombardment. Etching gallium nitride after ion bombardment produces defective layers. However, the etching that initiates at the intrinsic crystal threading dislocations can generate dislocation free gallium nitride film or layer.

Other embodiments are within the scope of the following claims.

1. A method for preparing III-V semiconductor film comprising:
irradiating a surface of a substrate including the III-V semiconductor; and
contacting the surface of the substrate while irradiating with a solution containing an etching solution to form the film on the substrate.

2. The method of claim 1, wherein the III-V semiconductor is selected from the group consisting of indium arsenide, indium phosphide, gallium arsenide, gallium phosphide, aluminum nitride, gallium antimonide, indium antimonide, aluminum arsenide, aluminum phosphide, aluminum antimonide, indium gallium arsenide, gallium arsenide phosphide, indium gallium arsenide phosphide, indium aluminum gallium arsenide, indium arsenide phosphide, indium gallium nitride, and aluminum gallium nitride.

3. The method of claim 1, wherein the III-V semiconductor is gallium nitride.

4. The method of claim 3, wherein the substrate includes a silicon doped, n-doped, un-doped, or p-doped gallium nitride on sapphire.

5. The method of claim 3, wherein the substrate includes bulk gallium nitride.

6. The method of claim 3, wherein the substrate includes gallium nitride on silicon carbide.

7. The method of claim 3, wherein the substrate includes gallium nitride on silicon.

8. The method of claim 1, wherein the etching solution includes hydrogen fluoride and hydrogen peroxide or potassium hydroxide.

9. (canceled)

10. The method of claim 1, wherein the surface of the substrate includes a plurality of dislocations.

11. The method of claim 1, wherein the etching solution etches selectively at the dislocations.

12. The method of claim 1, wherein the surface of the substrate is irradiated by an irradiation source, wherein the irradiation source has an energy greater than the bandgap of the III-V semiconductor.

13. The method of claim 1, wherein the surface of the substrate is irradiated by an ultraviolet light source, wherein the energy of the ultraviolet light source is greater than the bandgap of the III-V semiconductor.

14. The method of claim 1, wherein the surface of the substrate is irradiated by an X-ray or a gamma ray.

15. (canceled)

16. The method of claim 12, wherein the method further comprising controlling the intensity of the irradiation source.

17. The method of claim 1, wherein a portion of the surface of the substrate is coated with an electrode.

18. The method of claim 17, wherein the material of the electrode is selected from titanium, platinum, silver, and gold.

19. The method of claim 1, wherein the method further comprising applying an electric field at the surface of the substrate.

20. The method of claim 1, wherein the method further comprises drying the substrate.

21. The method of claim 1, wherein the thickness of the III-V semiconductor film is between 10 nanometers and 1 micron.

22. The method of claim 1, wherein the method further comprises transferring the III-V semiconductor film to a second substrate.

23. A film comprising dislocation free single crystalline III-V semiconductor, wherein the dislocation free single crystalline III-V semiconductor has a thickness of between 10 nanometers and 1 micron nanometers.

24. The film of claim 23, wherein the film includes a plurality of pores.

25. The film of claim 23, wherein the III-V semiconductor is gallium nitride.

26. The film of claim 25, wherein a plurality of gallium nitride wires protrude through the dislocation free single crystalline gallium nitride.

27. The film of claim 25, wherein the film further comprises a porous gallium nitride layer underneath the dislocation free single crystalline gallium nitride.

28. A structure comprising dislocation free single crystalline III-V semiconductor on a substrate, wherein the substrate is a polymer substrate, copper substrate, silicon substrate, glass substrate, silicon carbide substrate, sapphire substrate, quartz substrate, porcelain substrate, indium phosphide substrate, gallium nitride substrate, gallium arsenide substrate, beryllium oxide substrate, aluminum nitride substrate, alumina substrate, plastic substrate, or ceramic substrate.

29. A device for growing III-V semiconductor comprising a film, wherein the film includes dislocation free single crystalline III-V semiconductor, and wherein the film has a thickness of 10 nanometers to 1 micron.

30. The device of claim 29, wherein the III-V semiconductor is gallium nitride.
